(19) United States
(12) Patent Application Publication
(10) Pub. No.: US 2019/0300289 A1
(43) Pub. Date: Oct. 3, 2019

(54) MICRO-TRANSFER PRINTERS WITH ROLL STAMP(S)

(71) Applicant: X-Celeprint Limited, Cork (IE)

(72) Inventor: Ronald S. Cok, Rochester, NY (US)

(21) Appl. No.: 15/941,849

(22) Filed: Mar. 30, 2018

(51) Int. Cl. B65G 29/02; H01L 21/67; B81C 99/00

(52) U.S. Cl. CPC B65G 29/02; B81C 99/002; H01L 21/67121

(57) ABSTRACT

A roll micro-transfer printer comprises a source substrate having sacrificial portions spaced apart by anchors and micro-devices each disposed exclusively in association with a sacrificial portion and physically connected to at least one of the anchors by a tether. A roll stamp comprising a visco-elastic material disposed in alignment with the source substrate contacts micro-devices on the source substrate to fracture or separate the tether and adhere the micro-devices to the roll stamp. A destination substrate disposed in alignment with the roll stamp contacts micro-devices on the roll stamp and adheres the micro-devices to the destination substrate. The roll stamp is disposed to rotate about a roll stamp axis, the source substrate transport is disposed to translate in a source substrate direction orthogonal to the roll stamp axis, and the destination substrate transport is disposed to translate in a destination substrate direction opposite to the source substrate direction.

### FIELD OF THE INVENTION

The present invention relates generally to micro-transfer printing micro-scale devices from source substrates to destination substrates and, in particular, to roll-to-roll manufacturing.

### BACKGROUND OF THE INVENTION

Monocrystalline semiconductor processing techniques are limited to relatively small size substrates. For example, semiconductor wafers photolithographically processed at very high resolutions have sizes of up to 300 mm in diameter and are limited by the photolithographic handling and processing equipment. Devices made from the wafers typically provide high performance and are relatively expensive.

Roll-to-roll manufacturing processes employ much larger substrates at a reduced cost compared to monocrystalline wafer processing. Roll-to-roll manufacturing is the process of applying coatings or performing other processes on a roll of flexible material. The flexible material is initially wound in a roll, the roll is turned about an axis to unwind or spool successive portions of the flexible material to a flat configuration for deposition or processing, and then rewound into a second roll of coated or processed flexible material. This process is also known as reel-to-reel processing or web processing, where the flexible material is referred to as a web. After processing, the web can be slit to a desired width and then cut to a desired sheet size.

Roll-to-roll processing has been used for many years to provide low-cost manufacturing for coated substrates such as photographic film and paper. In recent years, electronic devices have been printed on substrates in a roll-to-roll process by patterning a coating or applying patterned coatings to the web. For example, large, thin-film transistor circuits can be patterned onto the web. Such electronic devices typically have relatively low performance compared to monocrystalline semiconductor devices, for example the printed conductive or semiconductor materials such as doped polythiophenes typically have a lower electron mobility and current-carrying capacity as well as a coarser resolution. Inkjet and photolithographic processes are used in conjunction with roll-to-roll processing.

Roll-to-roll processes form electronically active components by pattern-wise printing materials onto a flexible substrate to form flexible circuits. For example, KR20101488419 B1 entitled “Method for mass-producing of double side flexible printed circuit board by using roll-to-roll printing process and system thereof” discloses a method for mass-manufacturing double-sided flexible printed circuit boards using a roll-to-roll continuous printing process and system. U.S. Pat. No. 8,689,687 B2 entitled “Method and apparatus for manufacturing electronic device using roll-to-roll rotary pressing process” illustrates an apparatus for manufacturing electronic devices using a roll-to-roll rotary pressing process. KR100763493 entitled “Microcontact printing device of roll-to-roll printing type” describes a micro-contact printing device of roll-to-roll print type provided to form a micro metal pattern on a paper or plastic substrate by using an elastomer stamp enclosing an outer periphery of a roller. A related application KR100787237 entitled “Microcontact printing device of roll-print type using PDMS stamp” describes a polydimethylsiloxane stamp and KR100873516B1 entitled “Micro-contact printing device using an elastomeric stamp” uses a piezo actuator for displacement control. KR101240319B1 entitled “Roll imprint method and apparatus with dual stamp” uses a double stamp arrangement for imprinting a surface with a 3D nano-structure.

The above techniques have some limitations. Despite processing methods used to improve the performance of thin-film transistors, such transistors can provide performance that is lower than the performance of other integrated circuits formed in mono-crystalline semiconductor material. Semiconductor material and active components can be provided only on portions of the substrate, leading to wasted material and processing costs. The choice of substrate materials (e.g., a web) can also be limited by the processing steps necessary to process the semiconductor material and the photo-lithographic steps used to pattern the active components. For example, plastic substrates have a limited chemical and heat tolerance and do not readily survive photo-lithographic processing. Furthermore, the manufacturing equipment used to process large substrates with thin-film circuitry is relatively expensive.

Some methods used for distributing electronically functional components over a relatively large substrate (such as circuit board assembly) include pick-and-place technologies for integrated circuits provided in a variety of packages, for example, pin-grid arrays, ball-grid arrays, and flip-chips. However, these techniques can be limited to relatively large integrated circuits or components that can be placed and do not take advantage of the efficiencies provided by roll-to-roll processing.

Another method for transferring active components from one substrate to another is described in “AMOLED Displays using Transfer-Printed Integrated Circuits” published in the Proceedings of the 2009 Society for Information Display International Symposium Jun. 2-5, 2009, in San Antonio Tex., US, vol. 40, Book 2, ISSN 0009-0966X, paper 63.2 p. 947. In this approach, small integrated circuits are formed over a buried oxide layer on the process side of a crystalline wafer. The small integrated circuits, or chiplets, are released from the wafer by etching the buried oxide layer formed beneath the circuits. A PDMS stamp is pressed against the wafer and the process side of the chiplets is adhered to the stamp. The chiplets are pressed against a destination substrate or backplane coated with an adhesive and thereby adhered to the destination substrate. The adhesive is subsequently cured. In another example, U.S. Pat. No. 8,722,458 entitled Optical Systems Fabricated by Printing-Based Assembly teaches transferring light-emitting, light-sensing, or light-collecting semiconductor elements from a wafer substrate to a destination substrate or backplane. These transfer methods employ linear motion which requires the stamp to stop and start each time the stamp comes into contact with the chiplets.

There is a need, therefore, for structures and methods that provide high-performance micro-devices on large substrates at a reduced cost with greater efficiency, and at higher speeds to provide high-performance electronic systems.

### SUMMARY OF THE INVENTION

According to certain embodiments of the present invention, a roll micro-transfer printer comprises a source substrate transport for transporting a source substrate. The source substrate comprises sacrificial portions spaced apart by anchors. A micro-device is disposed exclusively on, in, over, or under each of the sacrificial portions and physically connected to at least one of the anchors by one or more tethers. A roll stamp comprises a visco-elastic material disposed in alignment with the source substrate transport so that, when a source substrate is disposed on or in the source substrate transport, the roll stamp contacts one or more micro-devices to fracture or separate the one or more tethers physically connecting each of the one or more micro-devices to the source substrate and adhere the one or more micro-devices to the roll stamp. A destination substrate transport for transporting a destination substrate is disposed in alignment with the roll stamp so that, when one or more micro-devices are disposed on the roll stamp, the one or more micro-devices contact and adhere to the destination substrate. The roll stamp is disposed to rotate about a roll stamp axis, the source substrate transport is disposed to translate the source substrate in a source substrate direction orthogonal to the roll stamp axis, and the destination substrate transport is disposed to translate the destination substrate in a destination substrate direction opposite to the source substrate direction.

In some embodiments of the present invention, a source substrate is disposed on the source substrate transport and a destination substrate is disposed on the destination substrate transport and the roll micro-transfer printer is operated to translate the source substrate in a source substrate direction, to translate the destination in a destination substrate direction opposed to the source substrate direction, and to rotate the roll stamp so that micro-devices are micro-transfer printed from the source substrate to the destination substrate with the roll stamp.

In some embodiments of the present invention, a source substrate is one or more of a wafer, an intermediate substrate, a rigid sheet, and a flexible sheet. A destination substrate can be one or more of a wafer, an intermediate substrate, a rigid sheet, a flexible sheet, and a display substrate. The micro-device can be, without limitation, one or more of an integrated circuit, a sensor, and a light-emitting diode.

In certain embodiments, a cleaning roller rotates about a cleaning roller axis parallel to the roll stamp axis and is disposed to contact the roll stamp.

In some embodiments, micro-devices are arranged in one or more rows on a source substrate and a roll stamp contacts a row of micro-devices on the source substrate to transfer the row of micro-devices from the source substrate to the roll stamp and a destination substrate contacts a row of micro-devices on the roll stamp to transfer the row of micro-devices from the roll stamp to the destination substrate.

In some embodiments, a roll stamp has a roll stamp surface and comprises stamp posts that protrude from the roll stamp surface. Each stamp post is disposed to contact a micro-device on a source substrate.

In some embodiments, micro-devices are arranged in rows on a source substrate and one or more stamp posts contact a subset of the micro-devices in a row. In some embodiments, the stamp posts contact micro-devices in a subset of the rows. In some embodiments, the stamp posts contact a subset of micro-devices in a row and the stamp posts contact micro-devices in a subset of the rows.

In some embodiments of the present invention, a roll stamp is a first roll stamp, micro-devices are first micro-devices, and one or more tethers are one or more first tethers. A source substrate comprises second sacrificial portions and a second micro-device is disposed exclusively on, in, over, or under each of the second sacrificial portions and physically connected to at least one anchor by one or more second tethers. A roll micro-transfer printer can comprise a second roll stamp comprising a visco-elastic material disposed in alignment with the source substrate transport so that, when a source substrate is disposed on the source substrate transport, the second roll stamp contacts one or more second micro-devices to fracture or separate the one or more second tethers physically connecting each of the one or more second micro-devices to the source substrate and adheres the one or more second micro-devices to the second roll stamp. A destination substrate is disposed in alignment with the second roll stamp so that, when one or more second micro-devices are disposed on the second roll stamp, the one or more second micro-devices contact and adhere to the destination substrate.

In some embodiments, the printer comprises a controller that controls (i) the roll stamp to rotate about the roll stamp axis, (ii) the source substrate transport to translate the source substrate in the source substrate direction, and (iii) the destination substrate transport to translate the destination substrate in the destination substrate direction.

In some embodiments, a first roll stamp comprises first stamp posts, a second roll stamp comprises second stamp posts and the first stamp posts are offset with respect to the second stamp posts in the roll stamp axis direction. The first roll stamp can be offset with respect to the second roll stamp in the roll stamp axis direction. In some embodiments, a controller controls a first roll stamp to contact first micro-devices of a source substrate at a first substrate offset at a first time and a second roll stamp to contact second micro-devices of the source substrate at a second substrate offset different from the first substrate offset and at a second time different from the first time.

In some embodiments, a source substrate is a first source substrate, a roll stamp is a first roll stamp, micro-devices are first micro-devices, and one or more tethers are one or more first tethers. A roll micro-transfer printer can comprise a second roll stamp comprising a visco-elastic material disposed in alignment with a source substrate transport and disposed in alignment with a destination substrate transport, so that, when a second source substrate is disposed in the source substrate transport in alignment with the second roll stamp, the second source substrate comprising second sacrificial portions spaced apart by second anchors and a second micro-device is disposed exclusively on, in, over, or under each of the second sacrificial portions and physically connected to at least one of the second anchors by one or more second tethers, the second roll stamp contacts one or more second micro-devices to fracture or separate the one or more second tethers physically connecting each of the one or more second micro-devices to the second source substrate and adheres the one or more second micro-devices to the second roll stamp, and the second roll stamp contacts the destination substrate with one or more second micro-devices and adheres the one or more second micro-devices to the destination substrate. The first source substrate can be offset with respect to the second source substrate in the roll stamp axis direction.

In some embodiments of the present invention, a method of micro-transfer printing from a source substrate to a destination substrate with a roll stamp comprises providing a roll micro-transfer printer comprising a source substrate transport for transporting a source substrate disposed on or in the source substrate transport, the source substrate comprising sacrificial portions spaced apart by anchors and wherein a micro-device is disposed exclusively on, in, over, or under each of the sacrificial portions and physically connected to at least one of the anchors by one or more tethers, a roll stamp comprising a visco-elastic material disposed in alignment with the source substrate transport and source substrate, and a destination substrate transport for transporting a destination substrate disposed in alignment with the roll stamp. The roll stamp is disposed to rotate about a roll stamp axis, the source substrate transport is controlled to translate a source substrate in a source substrate direction orthogonal to the roll stamp axis, and the destination substrate transport is disposed to translate a destination substrate in a destination substrate direction opposite to the source substrate direction. The roll stamp rotates to contact the micro-devices physically connected to the source substrate and fracture or separate the one or more tethers physically connecting each of the micro-devices to adhere the micro-devices to the roll stamp, and the micro-devices on the roll stamp are subsequently contacted with the destination substrate to adhere the micro-devices to the destination substrate.

In some embodiments, micro-devices each disposed exclusively on, in, over, or under each sacrificial portion are disposed in rows on a source substrate and the method comprises rotating the roll stamp (i) to contact fewer than all of the micro-devices in a row, (ii) to contact micro-devices in fewer than all of the rows, or (iii) both (i) and (ii).

In some embodiments, a method of the present invention comprises disposing a source substrate on or in a source substrate transport at a first offset with respect to a destination substrate during a first time, micro-transfer printing a first subset of micro-devices from the source substrate to the destination substrate at the first time, disposing the source substrate on the source substrate transport at a second offset with respect to the destination substrate during a second time different from the first time, and subsequently micro-transfer printing a second subset of micro-devices different from the first subset of micro-devices from the source substrate to the destination substrate during the second time.

In some embodiments, the roll stamp is a first roll stamp, micro-devices each disposed exclusively on, in, over, or under each sacrificial portion are first micro-devices, and one or more tethers physically connecting each of the micro-devices to a source substrate are one or more first tethers. A roll micro-transfer printer can comprise a second roll stamp comprising a visco-elastic material disposed in alignment with the source substrate transport and disposed in alignment with the destination substrate transport, so that, when a second source substrate is disposed in the source substrate transport in alignment with the second roll stamp, the second source substrate comprising second sacrificial portions spaced apart by second anchors and a second micro-device is disposed exclusively on, in, over, or under each of the second sacrificial portions and physically connected to an anchor by one or more second tethers, the method comprises rotating the second roll stamp to contact the one or more second micro-devices and fracture or separate the one or more second tethers physically connecting each of the one or more second micro-devices to the second source substrate to adhere the one or more second micro-devices to the second roll stamp, and subsequently contacting the one or more second micro-devices disposed on the second roll stamp with the destination substrate to adhere the second micro-devices to the destination substrate.

In some embodiments, the roll micro-transfer printer comprises a controller that controls (i) the roll stamp to rotate about the roll stamp axis, (ii) the source substrate transport to translate the source substrate in the source substrate direction, and (iii) the destination substrate transport to translate the destination substrate in the destination substrate direction.

In some embodiments, the micro-devices comprise light-emitting elements. In some embodiments, the light-emitting elements are inorganic light-emitting diodes. In some embodiments, the inorganic light-emitting diodes are micro-transfer printed light-emitting diodes each comprising a broken (e.g., fractured) or separated tether. In some embodiments, each micro-device has at least one or more of a width from 2 to 5 μm, 5 to 10 μm, 10 to 20 μm, or 20 to 50 μm, a length from 2 to 5 μm, 5 to 10 μm, 10 to 20 μm, or 20 to 50 μm, and a thickness from 2 to 5 μm, 4 to 10 μm, 10 to 20 μm, or 20 to 50 μm. In other embodiments, each micro-device has at least one or more of a width from 50 to 100 μm, 100 to 250 μm, 250 to 500 μm, or 500 to 999 μm, a length from 50 to 100 μm, 100 to 250 μm, 250 to 500 μm, or 500 to 999 μm, and a thickness from 5 to 50 μm or 50 to 100 μm.

Certain embodiments of the present invention provide, inter alia, methods, devices, and systems that enable the transfer of high-performance micro-devices from a source to a destination substrate with lower cost, with greater efficiency, and at higher speeds.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1A is a schematic cross section, according to exemplary embodiments of the present invention;

FIG. 1B is a perspective, according to exemplary embodiments of the present invention corresponding to FIG. 1A;

FIG. 2 is a detail schematic cross section of a micro-device on a source substrate, according to exemplary embodiments of the present invention;

FIG. 3 is a detail schematic cross section of a micro-device removed from a source substrate with a roll stamp, according to exemplary embodiments of the present invention;

FIG. 4 is a detail schematic cross section of a micro-device adhered to a destination substrate with a roll stamp, according to exemplary embodiments of the present invention;

FIG. 5 is a detail schematic cross section of a micro-device on a source substrate, according to exemplary embodiments of the present invention;

FIG. 6 is a schematic cross section of a printer that micro-transfer prints a subset of micro-devices from a source substrate to a destination substrate, according to exemplary embodiments of the present invention;

FIG. 7 is a perspective of a printer comprising two offset roll stamps, according to exemplary embodiments of the present invention;

FIG. 8 is a schematic cross section of a printer that micro-transfer prints micro-devices from a flexible roll source substrate to a flexible roll destination substrate, according to exemplary embodiments of the present invention;

FIG. 9 is a schematic cross section that micro-transfer print micro-devices from a flexible roll source substrate to a flexible roll destination substrate using contact rollers, according to exemplary embodiments of the present invention; and

FIGS. 10-12 are flow diagrams illustrating exemplary methods according to illustrative embodiments of the present invention.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not drawn to scale since the variation in size of various elements in the Figures is too great to permit depiction to scale.

### DETAILED DESCRIPTION OF THE INVENTION

The present invention provides, inter alia, systems and methods for micro-transfer printing micro-devices from a source substrate to a destination substrate with a roll micro-transfer printer. A source substrate can be a native source substrate on which the micro-devices are formed, and a destination substrate can be any suitable surface, including glass and plastic surfaces. A source substrate can be a flexible substrate provided in roll form or a series of relatively planar rigid substrates provided in a serial stream. Likewise, a destination substrate can be a flexible substrate provided in roll form or a series of relatively planar rigid substrates provided in a serial stream. A roll micro-transfer printer can comprise a visco-elastic roll stamp, for example a cylinder or roller rotating about an axis of the cylinder or roller. The roll stamp contacts the source substrate and destination substrate to transfer micro-devices from the source substrate to the destination substrate. The source and destination substrates move in opposite directions corresponding to the direction of their contact with the rotating cylinder. The contact between the roll stamp and the substrates can be in a planar configuration or in a curve.

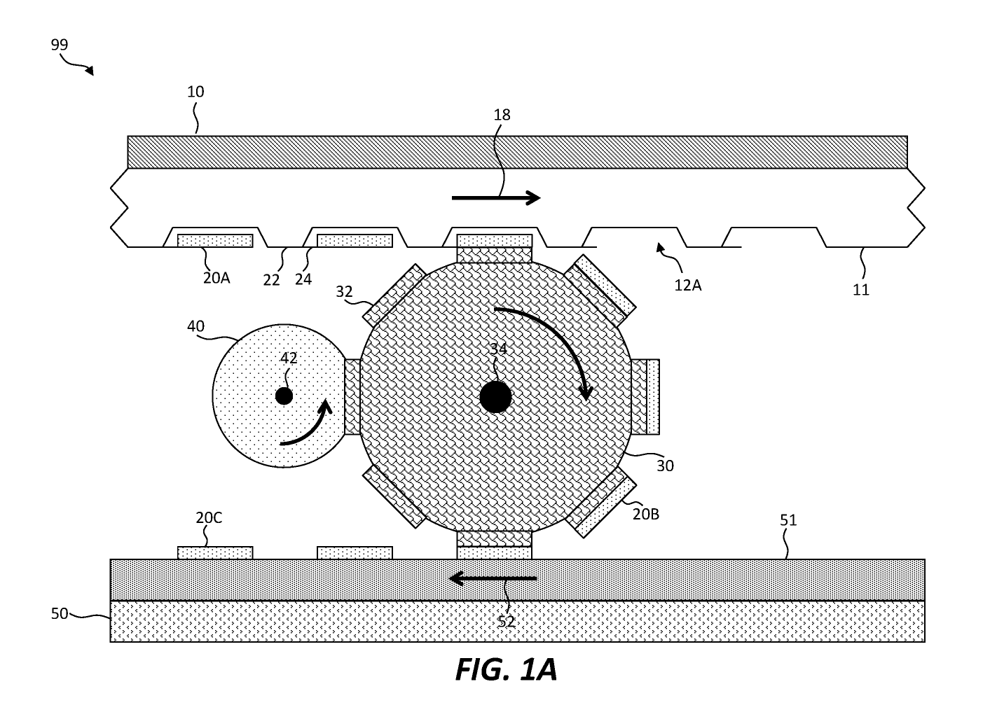

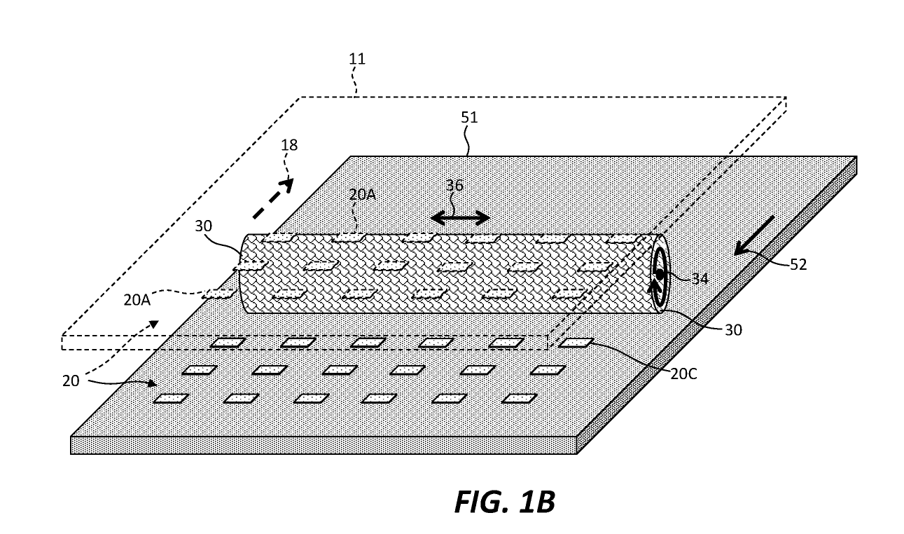

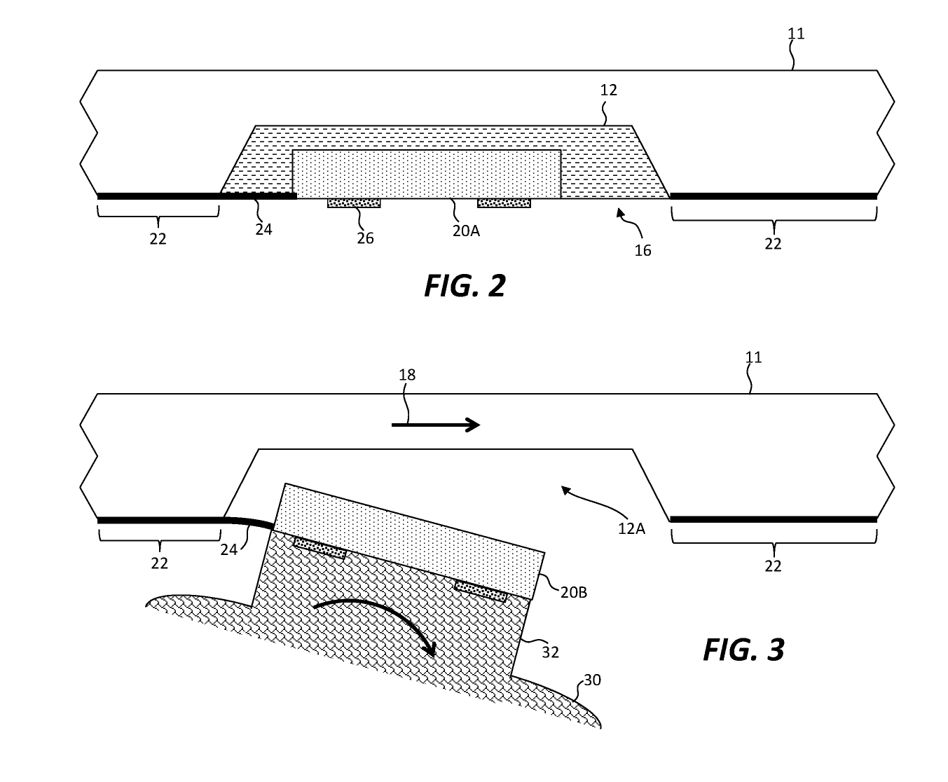

Referring to FIG. 1A in a schematic cross section, to FIG. 1B in a corresponding perspective, and to FIGS. 2, 3 and 4 in detail schematic cross sections, a roll micro-transfer printer 99, in certain embodiments of the present invention, comprises a source substrate transport 10 for transporting a source substrate 11. A source substrate transport 10 can be, for example, a substrate holder (e.g., a holder comprising one or more clamps), an element with a surface on which a source substrate 11 can be disposed (e.g., attached or suctioned to) (e.g., as shown in FIG. 1A), or another suitable means for securing a source substrate 11 during printing. A source substrate transport 10 can contact or otherwise secure all or at least a portion of a source substrate 11 (e.g., a surface of a source substrate 11). A source substrate 11 comprises sacrificial portions 12 spaced apart by anchors 22. One or more micro-devices 20A are disposed exclusively on, in, over, or under each sacrificial portion 12 and are physically connected to an anchor 22 by one or more tethers 24.

A roll stamp 30 comprising a visco-elastic material, such as PDMS (polydimethylsiloxane), is disposed in alignment with a source substrate transport 10 and source substrate 11 to contact one or more micro-device 20A attached to the source substrate 11 and fracture or separate the one or more tethers 24 to adhere the one or more micro-device 20A to the roll stamp 30. The roll stamp can be primarily cylindrical. In certain embodiments of the present invention, a roll stamp 30 comprises a cylinder with a visco-elastic material formed in a layer or wrapped around the cylinder.

A destination substrate transport 50 for transporting a destination substrate 51 is disposed in alignment with the roll stamp 30. A destination substrate transport 50 can be, for example, a substrate holder (e.g., a holder comprising one or more clamps), an element with a surface on which a destination substrate 51 can be disposed (e.g., attached or suctioned to) (e.g., as shown in FIG. 1A), or another suitable means for securing a destination substrate 51 during printing. A destination substrate transport 50 can contact or otherwise secure all or at least a portion of a destination substrate 51 (e.g., a surface of a destination substrate 51). The destination substrate 51 contacts one or more micro-devices 20B on the roll stamp 30 and adheres the one or more micro-devices 20C to the destination substrate 51. (The micro-devices are collectively or generically referred to as micro-devices 20 but are indicated in the figures as micro-devices 20A when attached to the source substrate 11, as micro-devices 20B when adhered to the roll stamp 30, and as micro-devices 20C when adhered to the destination substrate 51.)

The roll stamp 30 is disposed (e.g., controlled) to rotate about a roll stamp axis 34 that extends in a roll-stamp axis direction 36. A source substrate transport 10 is disposed (e.g., controlled) to translate a source substrate 11 in a source substrate direction 18 orthogonal to the roll-stamp axis direction 36, and a destination substrate transport 50 is disposed (e.g., controlled) to translate a destination substrate 51 in a destination substrate direction 52 opposite to the source substrate direction 18. Translation and rotation can occur through mechanical means or by a controller (e.g., electromechanically), for example. An opposite direction can be, but is not necessarily a parallel direction, but is at least partially in an opposed direction. That is, vectors describing the directions in a common dimension are opposed so that, for example the x dimension of the source substrate direction 18 is opposed to the x dimension of the destination substrate direction 52. The roll stamp 30, source substrate transport 10, and destination substrate transport 50 can be controlled by a controller, for example a control computer incorporating integrated circuits in conjunction with a mechanical assembly responsive to control signals provided by the control computer.

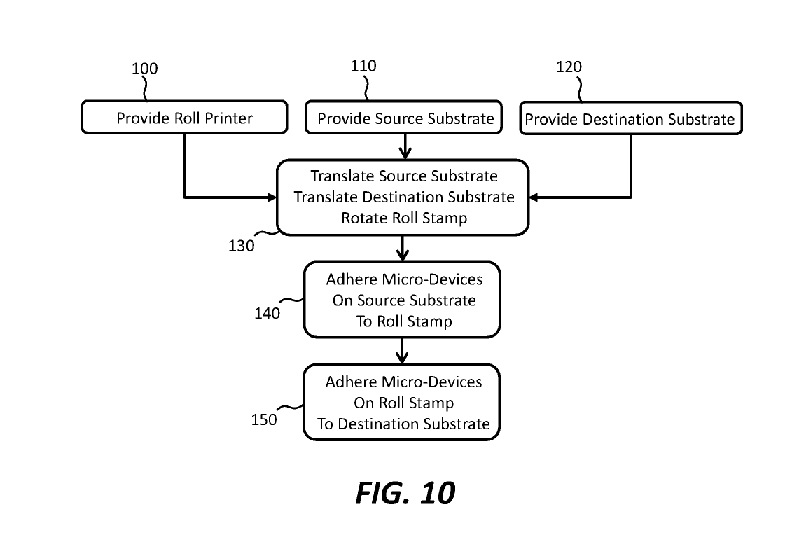

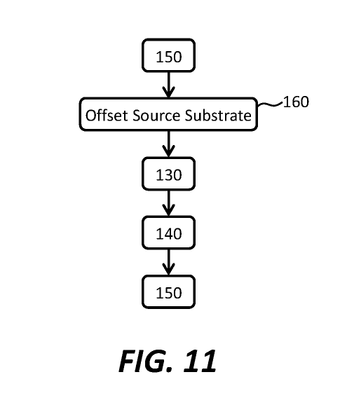

In some embodiments, a source substrate 11 is a source wafer, for example a native substrate on which one or more micro-devices 20A are formed or disposed, such as a native semiconductor wafer, or an intermediate substrate on which one or more micro-devices 20 are assembled using micro-transfer printing, for example in a circuit employing compound micro-assembly and processed using photolithography. A source substrate 11 can be rigid and planar and can be a sheet. In some embodiments, a source substrate 11 is a flexible substrate, such as a web, and can be wound in a roll on a feed roller 60, unwound for micro-transfer printing, and then wound up again in a roll on a take-up roller 62 (e.g., as shown in FIGS. 8 and 9).

Similarly, in some embodiments, a destination substrate 51 is a substrate, such as a glass or plastic substrate to which one or more micro-devices 20C are adhered after printing. A destination substrate 51 can be a display substrate, an intermediate substrate, or a wafer. A destination substrate 51 can be rigid and planar and can be a sheet. In some embodiments, a destination substrate 51 is a flexible substrate, such as a web, and can be wound in a roll on a feed roller 60, unwound for micro-transfer printing, and then wound up again in a roll on a take-up roller 62 (e.g., as shown in FIGS. 8 and 9).

A roll stamp 30 can comprise a cylinder with a roll stamp surface and can comprise one or more protruding stamp posts 32 that contact micro-devices 20A on a source substrate 11, adhere micro-devices 20B to stamp posts 32, and then contact the micro-devices 20B to a destination substrate 51 to adhere the micro-devices 20C to the destination substrate 51. In some embodiments, a roll stamp 30 does not have protruding stamp posts 32.

In some embodiments, micro-devices 20 are one or more of an integrated circuit, a sensor, and a light-emitting diode. In certain embodiments of the present invention, other micro-devices 20 are included, such as small circuits electrically connected on an intermediate substrate, for example in a structure using compound micro-assembly (e.g., thereby forming a compound micro-system). Certain embodiments of the present invention have the advantage that very small micro-devices 20 can be transferred from source to destination substrates, for example micro-devices with at least one of a thickness less than or equal to 20 μm and a length less than or equal to 100 μm, 50 μm, 20 μm, 10 μm, or 5 μm and a width less than or equal to 100 μm, 50 μm, 20 μm, 10 μm, or 5 μm. Such small devices cannot be readily picked up from a source supply and accurately disposed on a destination surface using conventional methods. In particular, the use of one or more tethers 24 to precisely locate each transferable micro-device 20 on a source substrate 11 and stamp posts 32 on a roll stamp 30 to pick up the micro-devices 20 enables very accurate, efficient, and rapid micro-device 20 from a source substrate 11 to a destination substrate 51.

A roll micro-transfer printer 99 can comprise a control computer and mechanical assembly that controls a source substrate transport 10, a destination substrate transport 50, and a roll stamp 30. In operation, a source substrate transport 10 is disposed (e.g., controlled) to translate a source substrate 11 in a source substrate direction 18 and a destination substrate transport 50 is disposed (e.g., controlled) to translate a destination substrate 51 in a destination substrate direction 52 opposite to the source substrate direction 18. A roll stamp 30 is rotated about its roll stamp axis 34 so that the surface or the stamp posts 32 of the roll stamp 30 contact micro-devices 20A on a source substrate 11 at a speed and in a direction matching the speed and direction of the source substrate 11. Likewise, a surface or stamp posts 32 of the roll stamp 30 contact a destination substrate 51 with micro-devices 20B on the surface or stamp posts 32 of the roll stamp 30 (for example at a location on the roll stamp 30 diametrically opposite the contact with the source substrate 11) at a speed and in a direction matching the speed and direction of the destination substrate 51. Thus, a source substrate 11 and a destination substrate 51 can move at the same speed in opposite directions.

As shown in the detail of FIG. 2, a source substrate 11 has sacrificial portions 12 separated by anchors 22. One or more tethers 24 physically connect each micro-device 20A to one or more anchors 22 (e.g., one tether 24 is shown in FIG. 2). Each micro-device 20 can have electrical contacts 26, for example to make electrical contact with a circuit in a micro-device 20. Each sacrificial portion 12 is exposed through an opening 16 that allows ingress of an etchant to the sacrificial portion 12.

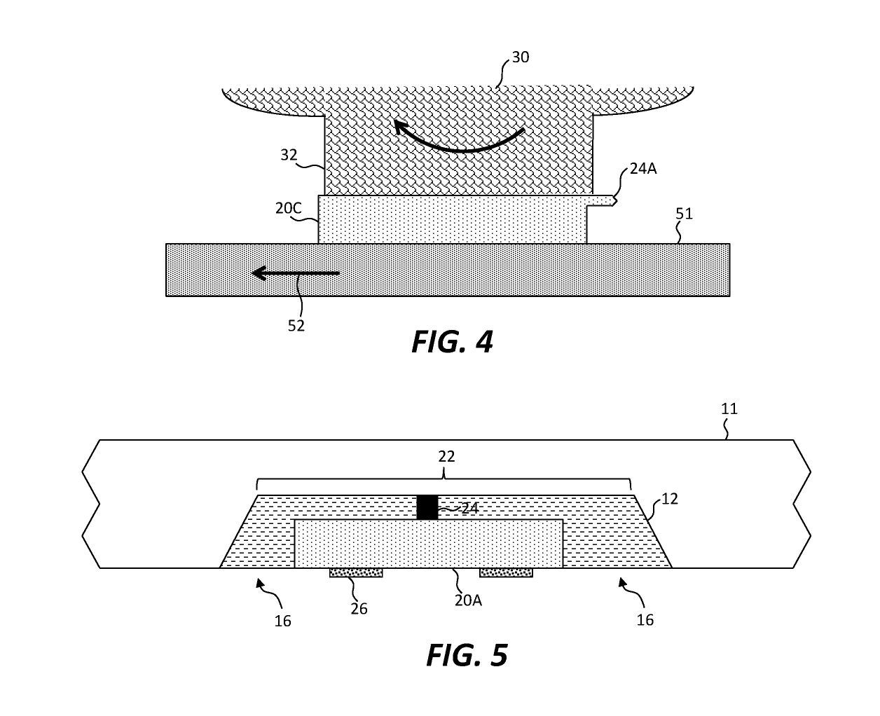

Referring to the detail of FIG. 3, sacrificial portions 12 are etched to remove sacrificial material and leave a gap 12A of space devoid of solid material, so that only one or more tethers 24 physically connect each micro-device 20A to one or more anchors 22 (e.g., one tether 24 is shown in FIG. 3) and a source substrate 11. Thus, sacrificial portions 12 can comprise sacrificial material before etching and empty space forming a gap 12A after etching the sacrificial material. The gap 12A can be filled with the atmospheric gases or a nitrogen gas.

A source substrate 11 translates in a source substrate direction 18 and a surface or stamp post 32 of a roll stamp 30 rotates into contact with and adheres a micro-device 20A to the stamp post 32 or stamp surface. As a stamp post 32 or surface contact rotates away from the source substrate 11 with an adhered micro-device 20, the tether 24 fractures or separate, leaving the micro-device 20B adhered to a stamp post 32 or surface of the roll stamp 30.

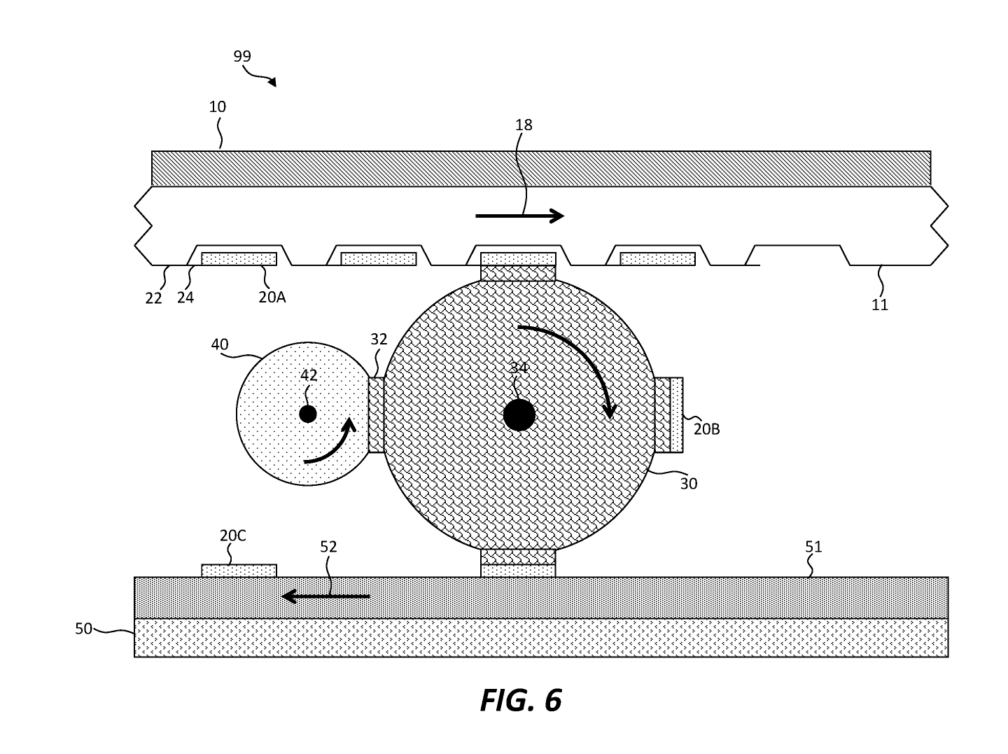

Referring to FIG. 4, a destination substrate 51 translates in a destination substrate direction 52 and a surface or stamp post 32 of a roll stamp 30 rotates into contact with and adheres a micro-device 20B with a fractured tether 24A on the roll stamp 30 to the destination substrate 51. As the stamp post 32 or surface contact rotates away from the destination substrate 51, a micro-device 20C is left adhered to the destination substrate 51. A destination substrate 51 can include a curable adhesive layer that adheres a micro-device 20C to the destination substrate 51 and is subsequently cured to permanently affix the micro-device 20C to the destination substrate 51.

As shown in FIG. 1A, a cleaning roller 40 can contact a surface or stamp posts 32 of a roll stamp 30 to remove any debris from stamp posts 32 or surface, improving the yield of micro-device 20 pick-up from a source substrate 11 or print to a destination substrate 51. The cleaning roller 40 can rotate about a cleaning roller axis 42 arranged with a roll-stamp axis direction 36 parallel to a roll stamp axis 34. A surface of the cleaning roller 40 is disposed to contact a roll stamp 30, for example stamp posts 32 or a surface of a roll stamp 30.

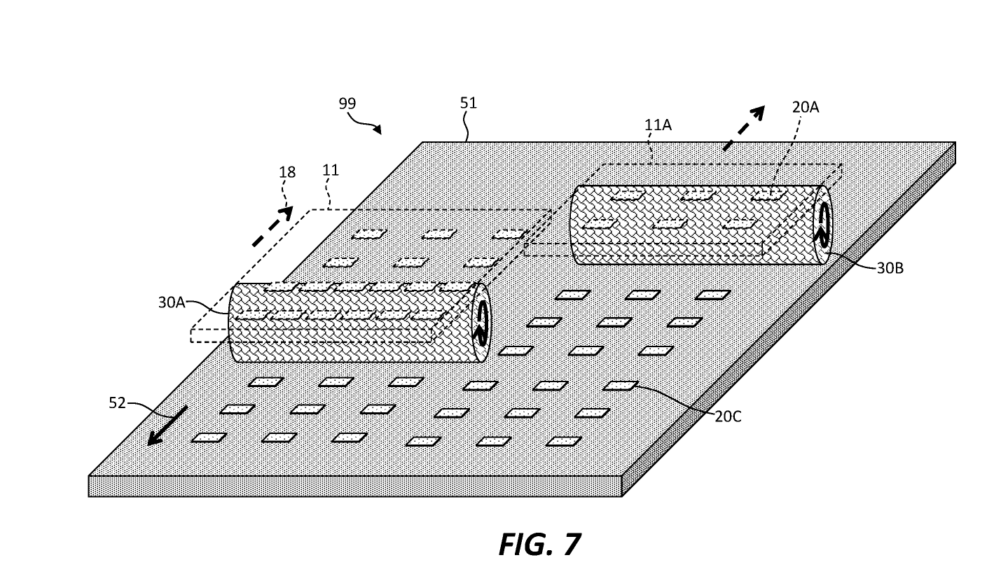

As shown in FIG. 1A, anchors 22 are distributed laterally between micro-devices 20A and one or more tethers 24 laterally connect micro-devices 20A to anchors 22. Referring to FIG. 5, in some embodiments of the present invention, anchors 22 of a source substrate 11 are disposed behind a back side of the micro-devices 20A opposite the front side contacted by the roll stamp 30 so that one or more tethers 24 extend from the backside of the micro-devices 20A through the sacrificial portion 12 to an anchor 22. When micro-devices 20A adhere to a surface or stamp post 32 of a roll stamp 30, one or more tethers 24 separate or delaminate from anchor 22 or micro-device 20A, or the one or more tethers 24 fracture, detaching micro-devices 20A from the source substrate 11 and adhering micro-devices 20B to the roll stamp 30.

Referring to FIG. 1B, in some embodiments of the present invention, micro-devices 20A are arranged in rows on a source substrate 11. A roll stamp 30 of the roll micro-transfer printer 99 contacts a row of micro-devices 20A on a source substrate 11 and contacts a row of micro-devices 20B on a destination substrate 51 to adhere the micro-devices 20C to the destination substrate 51. Thus, in certain embodiments, a roll micro-transfer printer 99 transfers a row of micro-devices 20A at a time from the source substrate 11 to the destination substrate 51 with the roll stamp 30 so that the arrangement of micro-devices 20A on the source substrate 11 matches the arrangement of the transferred micro-devices 20C on the destination substrate 51.

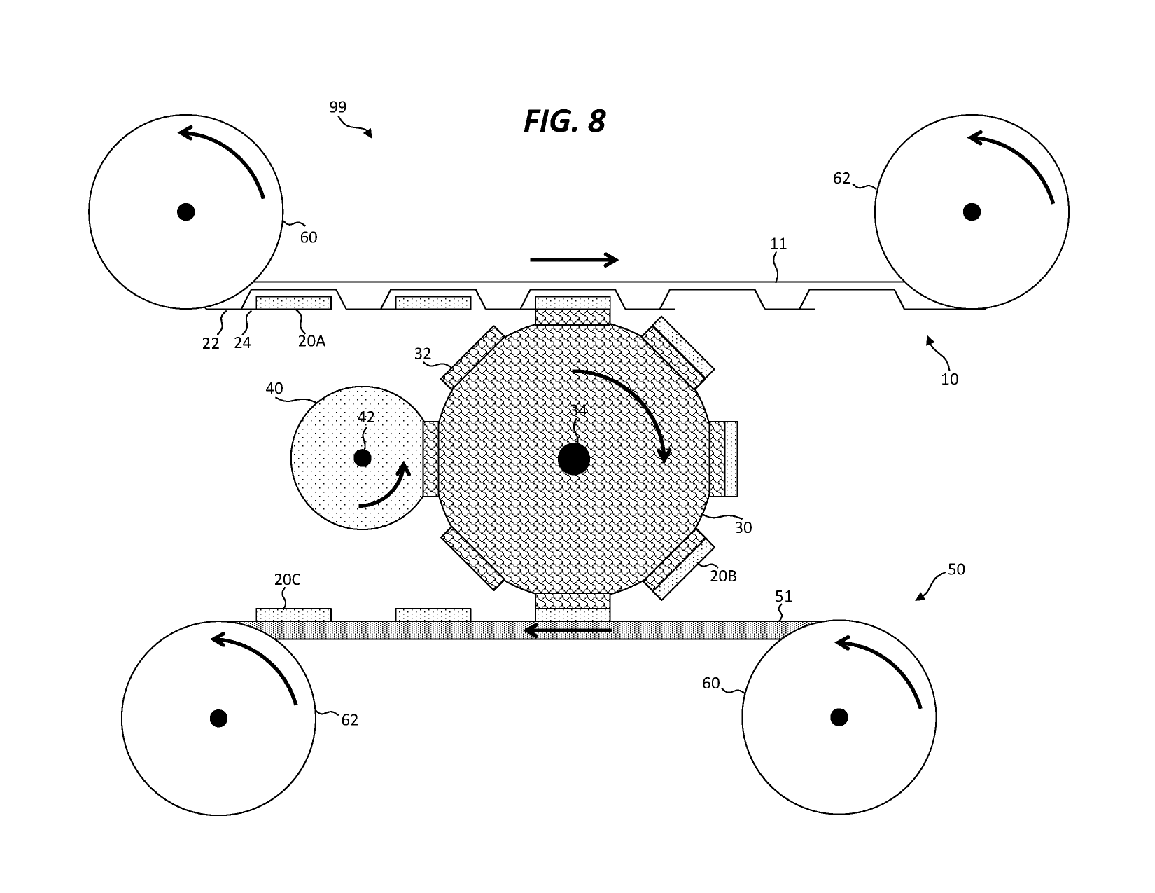

Referring to FIG. 6, a subset of rows of micro-devices 20A on a source substrate 11 can be picked up at a time. If a roll stamp 30 is provided with protruding stamp posts 32 that correspond to and align with a subset of micro-device 20A rows on a source substrate 11 when the roll stamp 30 rotates into contact with micro-devices 20A, only the corresponding subset of micro-device 20A rows are picked up by the stamp posts 32. As shown in FIG. 6, stamp posts 32 on a roll stamp 30 contact every other micro-device 20A row on the source substrate 11. If micro-devices 20 are arranged in rows, for example in a roll-stamp axis direction 36, micro-devices 20A from every other row will contact a stamp post 32, adhere to the stamp posts 32, and then, as the roll stamp 30 rotates, bring the micro-devices 20B disposed on the stamp posts 32 into contact with and adhere to a destination substrate 51. As shown in FIG. 6, the stamp posts 32 contact every other micro-device 20A in a source substrate direction 18. Thus, stamp posts 32 contact micro-devices 20A in a subset of the rows.

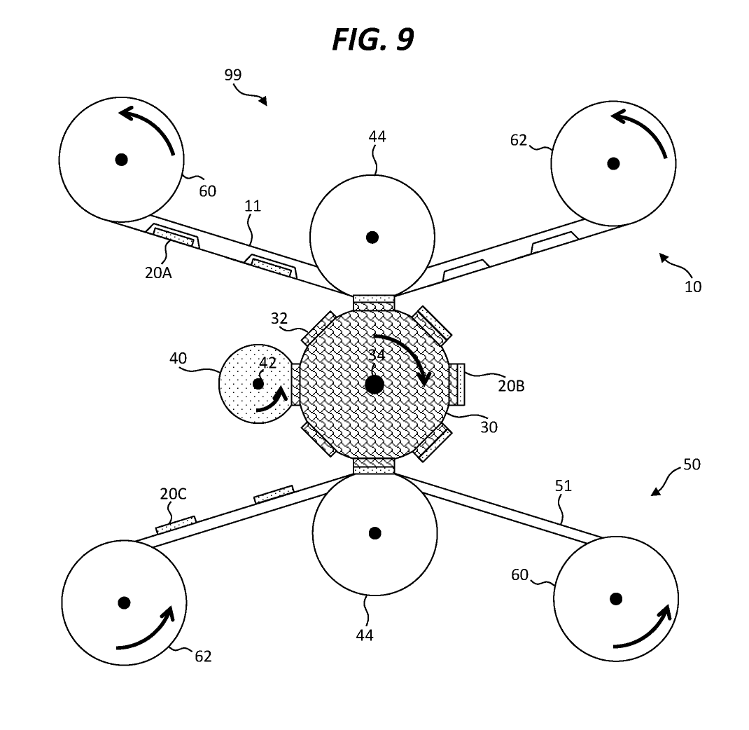

As shown in FIG. 7, in some embodiments, stamp posts 32 select a subset of micro-devices 20A within a row extending in a direction orthogonal to the source substrate direction 18, for example in a roll-stamp axis direction 36. Thus, stamp posts 32 contact a subset of micro-devices 20A in a row. Referring to FIG. 7, a roll stamp 30A contacts every other micro-device 20A in each row of micro-devices 20A on a source substrate 11 and transfers the contacted micro-devices 20B to a destination substrate 51, leaving the remaining every other micro-device 20A in each row on the source substrate 11A. Thus, micro-devices 20C on the destination substrate 51 are twice as far apart as originally on the source substrate 11.

In some embodiments of the present invention, micro-devices 20A are arranged in rows on a source substrate 11 and stamp posts 32 contact a subset of the micro-devices 20A in a row and the stamp posts 32 contact the micro-devices 20A in a subset of the rows. For example, if a source substrate 11 has a four-by-four array of micro-devices 20A and stamp posts 32 contact every other micro-device 20A in every other row, a destination substrate 51 will adhere a two-by-two array of micro-devices 20C spaced apart twice as far as on the source substrate 11.

Referring again to FIG. 7, in some embodiments a roll micro-transfer printer 99 comprises a second roll stamp 30B (where a first roll stamp 30 is labelled 30A) comprising a visco-elastic material disposed in alignment with a source substrate transport 10 and source substrate 11A (source substrate 11A is a source substrate 11 whose micro-devices 20A have been partially printed, source substrate 11 and source substrate 11A can be the same source substrate at different operational stages). In a first step, the first roll stamp 30A transfers a subset of micro-devices 20A on the original source substrate 11 to a destination substrate 51, leaving the remainder of the micro-devices 20A on the source substrate 11A. In a second step, the second roll stamp 30B transfers another subset (e.g., the remaining subset) of the micro-devices 20A on the source substrate 11A to the destination substrate 51. For example, the source substrate 11 can be moved relative to the destination substrate 51 after the first step and before the second step. A source substrate 11 can be moved relative to a destination substrate 51, for example, by moving a source substrate transport 10 while the source substrate 11 remains fixed or the source substrate 11 can be disposed in a second location (different from its original location) on the source substrate transport 10. The second roll stamp 30B and source substrate 11A is offset with respect to the first roll stamp 30A so that the second roll stamp 30B transfers micro-devices 20A from the source substrate 11A to a different portion of the destination substrate 51. Thus, in the exemplary embodiment shown in FIG. 7, the micro-devices 20A on the original source substrate 11 have been micro-transfer printed in two steps with two roll stamps 30A, 30B to two different portions of a destination substrate 51 so that the micro-devices 20C on the destination substrate 51 have one half the spatial density and are distributed over twice the area of the micro-devices 20A on the original source substrate 11. This process is called geometric magnification. Note that the same process could be accomplished by moving a destination substrate 51 with respect to a source substrate 11 (e.g., in a similar manner as exemplified above) and a single roll stamp 30 and sequentially performing the two transfer steps. Moreover, a single roll stamp 30 in a fixed position with respect to the destination substrate 51 could be used if only a portion of the single roll stamp 30 contacts the source substrate 11 each time micro-devices 20 are transferred from a source substrate 11 to a destination substrate 51.

Thus, in some embodiments, a roll micro-transfer printer 99 comprises a roll stamp 30 that is a first roll stamp 30A, micro-devices 20 are first micro-devices 20, and one or more tethers 24 are one or more first tethers 24. A source substrate 11 comprises second sacrificial portions 12 and a second micro-device 20A is disposed exclusively on, in, over, or under each of the second sacrificial portions 12 and is physically connected to at least one anchor 22 by one or more second tethers 24. The roll micro-transfer printer 99 comprises a second roll stamp 30B. When a source substrate 11A is disposed on a source substrate transport 10, a second roll stamp 30B contacts one or more second micro-devices 20A to fracture or separate one or more second tethers 24 physically connecting each of one or more second micro-devices 20 to the source substrate 11A and adheres one or more second micro-devices 20B to the second roll stamp 30B. The destination substrate 51 is disposed in alignment with the second roll stamp 30B so that, when one or more second micro-devices 20B are disposed on the second roll stamp 30B, the one or more second micro-devices 20C contact and adhere to the destination substrate 51.

A first roll stamp 30A can comprise first stamp posts 32, a second roll stamp 30B can comprise second stamp posts 32, wherein the first stamp posts 32 are offset with respect to the second stamp posts 32 in a roll-stamp axis direction 36. In some embodiments, a first roll stamp 30A is offset with respect to a second roll stamp 30B in a roll-stamp axis direction 36 to distribute micro-devices 20C over the surface of a destination substrate 51.

A roll micro-transfer printer 99 can comprise a controller such as a control computer or state machine that controls a first roll stamp 30A to contact first micro-devices 20A of a source substrate 11 at a first substrate offset at a first time and controls a second roll stamp 30B to contact second micro-devices 20A of the source substrate 11 at a second substrate offset different from the first substrate offset and at a second time different from the first time. The substrate offsets are with respect to the destination substrate 51 and destination substrate transport 50.

In the exemplary embodiment shown in FIG. 7, micro-devices 20A are transferred from a single source substrate 11 in two steps with two different roll stamps 30. In some embodiments of the present invention, micro-devices 20A are transferred from two different source substrates 11 with two different roll stamps 30A, 30B. Because two different source substrates 11 provide micro-devices 20A to the two different roll stamps 30, the two roll micro-transfer print operations can be done in one step at the same time. A source substrate transport 10 can transport both source substrates 11 together in appropriate alignment with the two different roll stamps 30A, 30B and a destination substrate 51.

Thus, in some embodiments, a source substrate 11 is a first source substrate 11, a roll stamp 30 is a first roll stamp 30A, micro-devices 20 are first micro-devices 20, and one or more tethers 24 are one or more first tethers 24. A roll micro-transfer printer 99 comprises a second roll stamp 30B comprising a visco-elastic material disposed in alignment with a source substrate transport 10 and the first source substrate 11 and disposed in alignment with a destination substrate transport 50 and destination substrate 51 so that when a second source substrate 11 is disposed in the source substrate transport 10 in alignment with the second roll stamp 30, the second source substrate 11 comprising second sacrificial portions 12 spaced apart by second anchors 22 and a second micro-device 20A is disposed exclusively on, in, over, or under each of the second sacrificial portions 12 and physically connected to at least one of the second anchors 22 by one or more second tethers 24, the second roll stamp 30B contacts one or more second micro-devices 20A to fracture or separate the one or more second tethers 24 physically connecting each of one or more second micro-devices 20 to the second source substrate 11 and adheres one or more second micro-devices 20B to the second roll stamp 30B, and the second roll stamp 30B contacts a destination substrate 51 with one or more second micro-devices 20B and adheres one or more second micro-devices 20C to the destination substrate 51. In some embodiments, a first source substrate 11 is offset with respect to a second source substrate 11 in a roll-stamp axis direction 36 to distribute the micro-devices 20C over the surface of the destination substrate 51.

Referring to FIGS. 8 and 9, in some embodiments of the present invention, a source substrate 11 or a destination substrate 51, or both are flexible substrates provided in a feed roll 60 and, after micro-transfer printing, wound up in a take-up roll 62. Referring to FIG. 8, the upper feed roll 60 and the upper take-up roll 62 form a source substrate transport 10 and the lower feed roll 60 and the lower take-up roll 62 form a destination substrate transport 50. Because, in certain embodiments, the individual micro-devices 20 are relatively small compared to the source substrate 11, even if the micro-devices 20 are rigid, the source substrate 11 and destination substrate 51 can be flexible in such a roll micro-transfer printer 99. For example, source and destination substrates 11, 51 can be thin glass or polymer. As shown in FIG. 8, the source and destination substrates 11, 51 are unwound by the source and destination substrate transports 10, 50, respectively, into a flat configuration for contact with a roll stamp 30 and micro-transfer printing from the source substrate 11 to a destination substrate 51. Micro-devices 20 can be physically connected to a flexible source substrate 10 by anchors 22 and tethers 24 (as shown by micro-device 20A in FIG. 8) or not. As shown in FIG. 9, if source or destination substrates 11, 51 are flexible, the web for each can pass over a contact roller 44 (e.g., which are parts of source substrate and destination transports 10, 50) against which a roll stamp 30 can pick-up or print micro-devices 20 so that the web is not in a flat configuration but rather is curved.

According to some embodiments, during operation of a roll micro-transfer printer 99, a source substrate 11 is located above a roll stamp 30 and the roll stamp 30 is located above a destination substrate 51 with respect to the direction of gravity. Thus, the force of gravity assists in removing micro-devices 20A from a source substrate 11 and in adhering micro-devices 20C to a destination substrate 51.

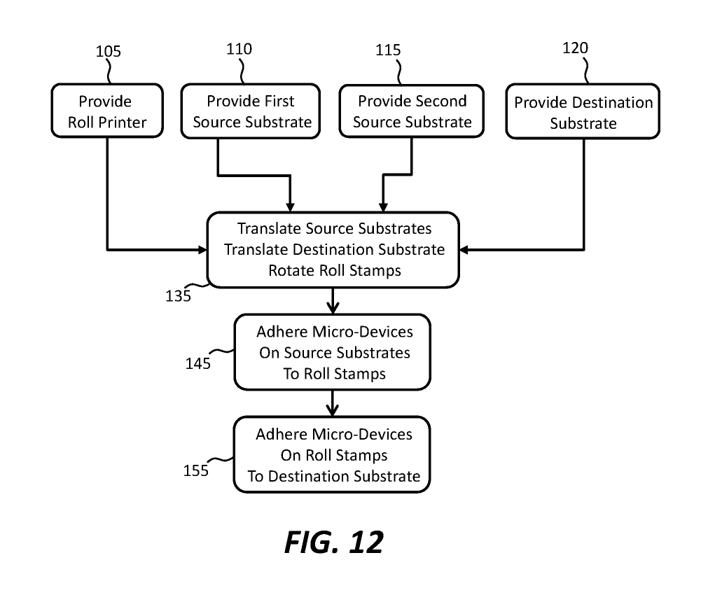

Referring to FIG. 10, an exemplary method of micro-transfer printing from a source substrate 11 to a destination substrate 51 with a roll stamp 30 comprises providing a roll micro-transfer printer 99 in step 100, providing a source substrate 11 with micro-devices 20A and disposing the source substrate 11 in a source substrate transport 10 in step 110, and providing a destination substrate 51 and disposing the destination substrate 51 in the destination substrate transport 50 in step 120. In step 130, a source substrate transport 10 translates a source substrate 11 in a source substrate direction 18, a destination substrate transport 50 translates a destination substrate 51 in a destination substrate direction 52, and a roll stamp 30 rotates to contact micro-devices 20A physically connected to the source substrate 11 and fracture or separate one or more tethers 24 physically connecting each of the micro-devices 20A to adhere the micro-devices 20B to the roll stamp 30 in step 140 and subsequently contacting the micro-devices 20B on the roll stamp 30 with the destination substrate 51 and adhere the micro-devices 20C to the destination substrate 51 in step 150.

In some embodiments, micro-devices 20A, each disposed exclusively on, in, over, or under each sacrificial portion 12, are disposed in rows on a source substrate 11. An exemplary method according to certain embodiments of the present invention comprises rotating a roll stamp 30 (i) to contact fewer than all of the micro-devices 20A in a row, (ii) to contact micro-devices 20A in fewer than all of the rows, or (iii) both (i) and (ii).

In some embodiments of the present invention, and referring to FIG. 11, an exemplary method comprises disposing a source substrate 11 on a source substrate transport 10 at a first offset with respect to a destination substrate 51 during a first time and micro-transfer printing a first subset of micro-devices 20 from the source substrate 11 to the destination substrate 51 at the first time (steps 100-150, as in FIG. 10). In a subsequent step, the method comprises disposing the source substrate 11 on the source substrate transport 10 at a second offset with respect to the destination substrate 51 during a second time different from the first time in step 160 and micro-transfer printing a second subset of micro-devices 20 different from the first subset of micro-devices 20 from the source substrate 11 to the destination substrate 51 during the second time in steps 130, 140, and 150.

Referring to FIG. 12, in some embodiments of the present invention, a roll micro-transfer printer 99 (provided in step 105 with two roll stamps 30) comprises a second roll stamp 30B comprising a visco-elastic material disposed in alignment with a source substrate transport 10 and source substrate 11 (provided in step 110) and disposed in alignment with a destination substrate transport 50 and destination substrate 51 (provided in step 120) so that when a second source substrate 11 is provided and disposed in a source substrate transport 10 in alignment with a second roll stamp 30B (step 115), the second source substrate 11 comprising second sacrificial portions spaced apart by second anchors 22 and a second micro-device 20A is disposed exclusively on, in, over, or under each of the second sacrificial portions 12 and physically connected to one or more anchors 22 by one or more second tethers 24, in step 135 the method comprises rotating the first and second roll stamps 30A, 30B to contact the one or more first and second micro-devices 20A respectively and fracture or separate the one or more first and second tethers 24 physically connecting each of the one or more first and second micro-devices 20A to the first and second respective source substrates 11 to adhere the one or more first and second micro-devices 20B to the corresponding respective first and second roll stamps 30A, 30B in step 145 and subsequently contacting the one or more first and second micro-devices 20B disposed on the first and second roll stamps 30A, 30B respectively with the destination substrate 51 to adhere the first and second micro-devices 20C to the destination substrate 51 in step 155.

According to certain embodiments of the present invention, micro-devices 20 can be any one or more of integrated circuits, sensors, and organic or inorganic light-emitting diodes. In some embodiments, each micro-device 20 has at least one or more of a width of no more than 100 μm or no more than 50 μm (e.g., from 2 μm to 5 μm, 5 μm to 10 μm, 10 μm to 20 μm, or 20 μm to 50 μm), a length of no more than 100 μm or no more than 50 μm (e.g., from 2 μm to 5 μm, 5 μm to 10 μm, 10 μm to 20 μm, or 20 μm to 50 μm), and a thickness of no more than 100 μm or no more than 50 μm (e.g., from 2 μm to 5 μm, 5 μm to 10 μm, 10 μm to 20 μm, or 20 μm to 50 μm). In some embodiments, each micro-device 20 has at least one of a width of no more than 1 mm (e.g., from 50 μm to 100 μm, 100 μm to 250 μm, 250 μm to 500 μm, or 500 μm to 999 μm), a length of no more than 1 mm (e.g., from 50 μm to 100 μm, 100 μm to 250 μm, 250 μm to 500 μm, or 500 μm to 999 μm), and a thickness from 5 μm to 50 μm or 50 μm to 100 μm. U.S. Pat. No. 6,825,559 describes methods of making micro-transfer-printable inorganic micro-devices 20; the disclosure of the methods of making micro-transfer-printable inorganic micro-devices of which is hereby incorporated by reference.

Structures and elements in accordance with certain embodiments of the present invention can be made and assembled using micro-transfer printing methods and materials. In some embodiments, micro-devices 20A are prepared on a native source substrate 11, for example a sapphire wafer with compound semiconductors such as GaN or silicon wafers with CMOS circuits thereon, with each type of micro-device 20A prepared on a different source substrate 11 and released for micro-transfer printing with one or more micro-device tethers 24 physically connecting the micro-devices 20A to an anchor 22 portion of the respective source substrate 11. In certain embodiments, micro-devices 20A are then contacted with a micro-transfer printing roll stamp 30 to fracture or otherwise break (or separate) the micro-device tethers 24 and adhere the micro-devices 20B to the transfer roll stamp 30, the transfer roll stamp 30 rotates, and the micro-devices 20C are contacted and adhered to the destination substrate 51.

For a discussion of micro-transfer printing techniques see U.S. Pat. Nos. 8,722,458, 7,622,367 and 8,506,867; the disclosure of micro-transfer printing techniques of each of which is hereby incorporated by reference. Methods of forming micro-transfer printable structures are described, for example, in the paper “AMOLED Displays using Transfer-Printed Integrated Circuits” (Journal of the Society for Information Display, 2011, DOI # 10.1889/JSID19.4.335, 1071-0922/11/1904-0335, pages 335-341) and U.S. Pat. No. 8,889,485. Micro-transfer printing using compound micro-assembly structures and methods can also be used with certain embodiments of the present invention, for example, as described in U.S. patent application Ser. No. 14/822,868, filed Aug. 10, 2015, entitled Compound Micro-Assembly Strategies and Devices; the disclosure of micro-transfer printing using compound micro-assembly structures of which is hereby incorporated by reference in their entirety. Additional details useful in understanding and performing aspects of the present invention are described in U.S. patent application Ser. No. 14/743,981, filed Jun. 18, 2015, entitled Micro Assembled LED Displays and Lighting Elements, the disclosure of which is hereby incorporated by reference in their entirety.

As is understood by those skilled in the art, the terms “over”, “under”, “above”, “below”, “beneath”, and “on” are relative terms and can be interchanged in reference to different orientations of the layers, elements, and substrates included in the present invention. For example, a first layer on a second layer, in some embodiments means a first layer directly on and in contact with a second layer. In other embodiments, a first layer on a second layer can include another layer there between.

Having described certain embodiments, it will now become apparent to one of skill in the art that other embodiments incorporating the concepts of the disclosure may be used. Therefore, the invention should not be limited to the described embodiments, but rather should be limited only by the spirit and scope of the following claims.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The invention has been described in detail with particular reference to certain embodiments thereof, but it will be understood that variations and modifications can be effected within the spirit and scope of the invention.

### PARTS LIST

10 source substrate transport
11 source substrate
11A partially printed source wafer
12 sacrificial portion
12A gap
16 opening
18 source substrate direction
20 micro-device
20A micro-device on source wafer
20B micro-device on roll stamp
20C micro-device on destination substrate
22 anchor
24 tether
24A fractured tether
26 electrical contact
30 roll stamp
30A first roll stamp
30B second roll stamp
32 stamp post
34 roll stamp axis
36 roll-stamp axis direction
40 cleaning roller
42 cleaning roller axis
44 contact roller
50 destination substrate transport
51 destination substrate
52 destination substrate direction
60 feed roller
62 take-up roller
99 roll micro-transfer printer
100 provide roll printer step
105 provide roll printer step
110 provide source substrate step
115 provide second source substrate step
120 provide destination substrate step
130 translate source and destination substrates and rotate roll stamp step
135 translate source and destination substrates and rotate roll stamps step
140 adhere micro-devices on source substrate to roll stamp step
145 adhere micro-devices on source substrate to roll stamps step
150 adhere micro-devices on roll stamp to destination substrate step
155 adhere micro-devices on roll stamps to destination substrate step
160 offset source substrate step

What is claimed:

1. A roll micro-transfer printer, comprising:
a source substrate transport for transporting a source substrate, wherein the source substrate comprises sacrificial portions spaced apart by anchors and wherein a micro-device is disposed exclusively on, in, over, or under each of the sacrificial portions and physically connected to at least one of the anchors by one or more tethers;
a roll stamp comprising a visco-elastic material disposed in alignment with the source substrate transport so that, when a source substrate is disposed on the source substrate transport, the roll stamp contacts one or more micro-devices to fracture or separate the one or more tethers physically connecting each of the one or more micro-devices to the source substrate and adhere the one or more micro-devices to the rollstamp;
a destination substrate transport for transporting a destination substrate disposed in alignment with the roll stamp so that, when one or more micro-devices are disposed on the roll stamp, the one or more micro-devices contact and adhere to the destination substrate,
wherein the roll stamp is disposed to rotate about a roll stamp axis, the source substrate transport is disposed to translate the source substrate in a source substrate direction orthogonal to the roll stamp axis, and the destination substrate transport is disposed to translate the destination substrate in a destination substrate direction opposite to the source substrate direction.

2. The roll micro-transfer printer of claim 1, wherein a source substrate is disposed on the source substrate transport and a destination substrate is disposed on the destination substrate transport.

3. The roll micro-transfer printer of claim 2, wherein the source substrate is one or more of a wafer, an intermediate substrate, a rigid sheet, and a flexible sheet.

4. The roll micro-transfer printer of claim 2, wherein the destination substrate is one or more of a wafer, an intermediate substrate, a rigid sheet, a flexible sheet, and a display substrate.

5. The roll micro-transfer printer of claim 2, wherein the micro-device is one or more of an integrated circuit, a sensor, and a light-emitting diode.

6. The roll micro-transfer printer of claim 1, comprising a cleaning roller that rotates about a cleaning roller axis parallel to the roll stamp axis, wherein the cleaning roller is disposed to contact the roll stamp.

7. The roll micro-transfer printer of claim 1, wherein the micro-devices are arranged in one or more rows on the source substrate and wherein the roll stamp contacts a row of micro-devices on the source substrate to transfer the row of micro-devices from the source substrate to the roll stamp and wherein the destination substrate contacts a row of micro-devices on the roll stamp to transfer the row of micro-devices from the roll stamp to the destination substrate.

8. The roll micro-transfer printer of claim 1, wherein the roll stamp has a roll stamp surface and comprises stamp posts that protrude from the roll stamp surface, each stamp post disposed to contact a micro-device on the source substrate.

9. The roll micro-transfer printer of claim 8, wherein the micro-devices are arranged in rows on the source substrate and the stamp posts contact a subset of the micro-devices in a row.

10. The roll micro-transfer printer of claim 8, wherein the micro-devices are arranged in rows on the source substrate and wherein the stamp posts contact the micro-devices in a subset of the rows.

11. The roll micro-transfer printer of claim 8, wherein the micro-devices are arranged in rows on the source substrate, wherein the stamp posts contact a subset of the micro-devices in a row, and wherein the stamp posts contact the micro-devices in a subset of the rows.

12. The roll micro-transfer printer of claim 1, wherein the roll stamp is a first roll stamp, the micro-devices are first micro-devices, and the one or more tethers are one or more first tethers, wherein the source substrate comprises second sacrificial portions and a second micro-device is disposed exclusively on, in, over, or under each of the second sacrificial portions and physically connected to at least one anchor by one or more second tethers, the roll micro-transfer printer comprising:
a second roll stamp comprising a visco-elastic material disposed in alignment with the source substrate transport so that, when a source substrate is disposed on the source substrate transport, the second roll stamp contacts one or more second micro-devices to fracture or separate the one or more second tethers physically connecting each of the one or more second micro-devices to the source substrate and adheres the one or more second micro-devices to the second roll stamp,
wherein the destination substrate is disposed in alignment with the second roll stamp so that, when one or more second micro-devices are disposed on the second roll stamp, the one or more second micro-devices contact and adhere to the destination substrate.

13. The roll micro-transfer printer of claim 12, wherein the first roll stamp comprises first stamp posts, the second roll stamp comprises second stamp posts and the first stamp posts are offset with respect to the second stamp posts in the roll stamp axis direction.

14. The roll micro-transfer printer of claim 12, wherein the first roll stamp is offset with respect to the second roll stamp in the roll stamp axis direction.

15. The roll micro-transfer printer of claim 14, comprising a controller that controls the first roll stamp to contact the first micro-devices of the source substrate at a first substrate offset at a first time and the second roll stamp to contact the second micro-devices of the source substrate at a second substrate offset different from the first substrate offset and at a second time different from the first time.

16. The roll micro-transfer printer of claim 1, comprising a controller that controls (i) the roll stamp to rotate about the roll stamp axis, (ii) the source substrate transport to translate the source substrate in the source substrate direction, and (iii) the destination substrate transport to translate the destination substrate in the destination substrate direction.

17. The roll micro-transfer printer of claim 1, wherein the source substrate is a first source substrate, the roll stamp is a first roll stamp, the micro-devices are first micro-devices, and the one or more tethers are one or more first tethers, and the roll micro-transfer printer comprises:
a second roll stamp comprising a visco-elastic material disposed in alignment with the source substrate transport and disposed in alignment with the destination substrate transport, so that,
when a second source substrate is disposed in the source substrate transport in alignment with the second roll stamp, the second source substrate comprising second sacrificial portions spaced apart by second anchors and a second micro-device is disposed exclusively on, in, over, or under each of the second sacrificial portions and physically connected to at least one of the second anchors by one or more second tethers,
the second roll stamp contacts one or more second micro-devices to fracture or separate the one or more second tethers physically connecting each of the one or more second micro-devices to the second source substrate and adheres the one or more second micro-devices to the second roll stamp, and
the second roll stamp contacts the destination substrate with one or more second micro-devices and adheres the one or more second micro-devices to the destination substrate.

18. The roll micro-transfer printer of claim 17, wherein the first source substrate is offset with respect to the second source substrate in the roll stamp axis direction.

19. A method of micro-transfer printing from a source substrate to a destination substrate with a roll stamp, comprising:
providing a roll micro-transfer printer comprising:
a source substrate transport for transporting a source substrate disposed on or in the source substrate transport, the source substrate comprising sacrificial portions spaced apart by anchors and wherein a micro-device is disposed exclusively on, in, over, or under each of the sacrificial portions and physically connected to at least one of the anchors by one or more tethers;
a roll stamp comprising a visco-elastic material disposed in alignment with the source substrate transport;
a destination substrate transport for transporting a destination substrate disposed in alignment with the roll stamp,
wherein the roll stamp is disposed to rotate about a roll stamp axis, the source substrate transport is disposed to translate a source substrate in a source substrate direction orthogonal to the roll stamp axis, and the destination substrate transport is disposed to translate a destination substrate in a destination substrate direction opposite to the source substrate direction;
translating the source substrate with the source substrate transport in the source substrate direction;
translating the destination substrate with the destination substrate transport in the destination substrate direction;
rotating the roll stamp to contact the micro-devices physically connected to the source substrate and fracture or separate the one or more tethers physically connecting each of the micro-devices to adhere the micro-devices to the roll stamp; and
subsequently contacting the micro-devices on the roll stamp with the destination substrate and adhere the micro-devices to the destination substrate.

20. The method of claim 19, wherein the micro-devices each disposed exclusively on, in, over, or under each sacrificial portion are disposed in rows on the source substrate and the method comprises rotating the roll stamp (i) to contact fewer than all of the micro-devices in a row, (ii) to contact micro-devices in fewer than all of the rows, or (iii) both (i) and (ii).

21. The method of claim 20, comprising:
disposing the source substrate on the source substrate transport at a first offset with respect to the destination substrate during a first time;
micro-transfer printing a first subset of micro-devices from the source substrate to the destination substrate at the first time;
disposing the source substrate on the source substrate transport at a second offset with respect to the destination substrate during a second time different from the first time; and
subsequently micro-transfer printing a second subset of micro-devices different from the first subset of micro-devices from the source substrate to the destination substrate during the second time.

22. The method of claim 19, wherein the roll stamp is a first roll stamp, the micro-devices each disposed exclusively on, in, over, or under each sacrificial portion are first micro-devices, and the one or more tethers physically connecting each of the micro-devices to the source substrate are one or more first tethers,
wherein the roll micro-transfer printer comprises a second roll stamp comprising a visco-elastic material disposed in alignment with the source substrate transport and disposed in alignment with the destination substrate transport, so that,
when a second source substrate is disposed in the source substrate transport in alignment with the second roll stamp, the second source substrate comprising second sacrificial portions spaced apart by second anchors and a second micro-device is disposed exclusively on, in, over, or under each of the second sacrificial portions and physically connected to an anchor by one or more second tethers,
the method comprises:
rotating the second roll stamp to contact the one or more second micro-devices and fracture or separate the one or more second tethers physically connecting each of the one or more second micro-devices to the second source substrate to adhere the one or more second micro-devices to the second roll stamp; and
subsequently contacting the one or more second micro-devices disposed on the second roll stamp with the destination substrate to adhere the second micro-devices to the destination substrate.

23. The method of claim 19, wherein the roll micro-transfer printer comprises a controller that controls (i) the roll stamp to rotate about the roll stamp axis, (ii) the source substrate transport to translate the source substrate in the source substrate direction, and (iii) the destination substrate transport to translate the destination substrate in the destination substrate direction.
